(19) United States
(12) Patent Application Publication
(10) Pub. No.: US 2002/0174823 A1
(43) Pub. Date: Nov. 28, 2002

(54) Chucking systems and methods

(75) Inventor: Neil Salstrom, Camas, WA (US)

Correspondence Address: Oliff & Berridge PLC, P.O. Box 19928, Alexandria, VA, 22320, US

(73) Assignee: SEH AMERICA, INC., VANCOUVER, WA

(21) Appl. No.: 09/864,295

(22) Filed: May 25, 2001

(51) Int. Cl. C30B 15/00; C30B 21/06; C30B 27/02; C30B 28/10; C30B 30/04

(52) U.S. Cl. 117/13

(57) ABSTRACT

A chuck body defines an axial bore for receiving an object or material to be chucked. A radially inclined bore that opens at least partially into an axial bore is provided in the chuck body. A chuck stopper is fitted into the radially inclined bore such that the chuck stopper extends at least partially into the axial bore to engage the object or material to be chucked. An axis of the radially inclined bore forms a non-zero angle α other than ninety degrees with respect to an axis A of the axial bore. The angle α is between zero and ninety degrees, preferably, between about forty-five and ninety degrees. Various means for maintaining the chuck stopper in the radially inclined bore in a desired chucking position may be used.

### BACKGROUND OF THE INVENTION

1. Field of Invention

This invention relates to chucking systems and chucking methods. More specifically, this invention relates to chucking systems and methods for use with a crystal growing apparatus.

2. Description of Related Art

A substantial majority of monocrystalline silicon used to make silicon wafers for the microelectronics industry is produced by crystal growing apparatus using the well-known Czochralski process. The Czochralski process basically involves melting high-purity polycrystalline silicon in a quartz crucible in a specially designed furnace to form a silicon melt. A small seed crystal is suspended above the silicon melt on a pull wire or the like, which is arranged to be raised and lowered in a generally vertical direction. The seed crystal is lowered into contact with the silicon melt. The seed crystal is then raised slowly from the silicon melt so that a silicon crystal rod is grown by drawing silicon from the silicon melt. Examples of Czochralski crystal growing systems are described in U.S. Pat. Nos. 5,406,905; 5,911,825; and 5,976,245, each of which is incorporated herein by reference in its entirety.

The seed crystal is typically secured in a chuck that is attached at one end to the pull wire. Specifically, it is known to use a chuck having a seed crystal bore at the end opposite the pull wire and an auxiliary bore or keyway on one side. The auxiliary bore is perpendicular to and opens into the seed crystal bore. The seed crystal bore receives a portion of the seed crystal and the auxiliary bore receives a chuck stopper. A shaped leading end of the chuck stopper is arranged to fit with a complementary-shaped portion of the seed crystal so that the seed crystal may be secured in the seed crystal bore by temporarily fixing the chuck stopper in the auxiliary bore.

### SUMMARY OF THE INVENTION

This invention is based upon the realization that the chucking operation and performance may be improved. Further, it would be desirable to be able to limit or reduce potential errors in chucking. Thus, this invention provides chucking systems and methods that are able to support greater weights. This invention also provides chucking systems and methods that help to ensure proper chucking by reducing or even eliminating potential errors.

In various embodiments of the chucking systems and methods of this invention, a system for chucking comprises a chuck body that defines an axial bore for receiving an object to be chucked and includes a radially inclined bore that opens at least partially into the axial bore. In various embodiments, the system also includes a chuck stopper that is adapted to fit into the radially inclined bore and extend partially into the axial bore.

In various embodiments of the chucking systems and methods of this invention, means for maintaining the chuck stopper in the radially inclined bore and extending partially into the axial bore is provided. In various embodiments, the means comprises a sleeve that is adapted to enclose a perimeter of the chuck body and at least a portion of the chuck stopper.

According to various embodiments, the radially inclined bore is inclined outwardly in a direction away from an open end of the axial bore. The radially inclined bore may be inclined at an angle of between zero and ninety degrees relative to an axis of the axial bore, preferably between about forty-five and ninety degrees. The radially inclined bore may be inclined at an angle of about eighty-eight degrees, about eighty-five degrees, about eighty degrees, about seventy-five degrees, about seventy degrees, about sixty-five degrees, about sixty degrees, about fifty-five degrees, or about fifty degrees.

These and other features and advantages of this invention are described in or are apparent from the following detailed description of various exemplary embodiments of the chucking systems and methods according to this invention.

### BRIEF DESCRIPTION OF THE DRAWINGS

The invention will be described in relation to the following drawings in which like reference numerals refer to like elements, and wherein:

FIG. 1 is a schematic view of a conventional crystal growing apparatus;

FIG. 2 is a perspective view of a chucking system according to an exemplary embodiment of this invention;

FIG. 3 is an elevation view of the chucking system of FIG. 2, with an associated sleeve illustrated in a non-chucking position;

FIG. 4 is a cross-sectional view of the chucking system taken along section line IV-IV in FIG. 3, with the associated sleeve illustrated in a chucking position;

FIG. 5 is an enlarged view of a portion V of FIG. 4, with the associated sleeve omitted;

FIG. 6 is a view of the chucking system shown in FIG. 3 as seen from the top;

FIG. 7 is a view of the chucking system shown in FIG. 3 as seen from the bottom;

FIG. 8 is a perspective view of an exemplary embodiment of a chuck stopper according to this invention;

FIG. 9 is a top view of the chuck stopper of FIG. 8;

FIG. 10 is a side view of the chuck stopper of FIG. 8; and

FIG. 11 is an end view of the chuck stopper shown in FIG. 10.

### DETAILED DESCRIPTION OF EXEMPLARY EMBODIMENTS

While the chucking systems and methods according to this invention are suitable for chucking in various types of apparatus, the chucking systems and methods of this invention are particularly advantageous for chucking in a crystal growing apparatus. Accordingly, for ease of understanding, the chucking systems and methods of this invention are described herein with reference to a typical crystal growing apparatus. This invention, however, is not to be considered to be limited by the description of the crystal growing apparatus or its use therewith.

According to the chucking systems and methods of this invention, a chuck body defines an axial bore for receiving an object or material to be chucked. A radially inclined bore that opens at least partially into an axial bore is provided in the chuck body. A chuck stopper is fitted into the radially inclined bore such that the chuck stopper extends at least partially into the axial bore to engage the object or material to be chucked. Because of the radially inclined bore arrangement, the chucking systems and methods of this invention support more weight than comparable chucks. Further, the radially inclined bore arrangement of this invention reduces or even prevents misinsertion of the chuck stopper by permitting a single, correct orientation for full insertion of the chuck stopper.

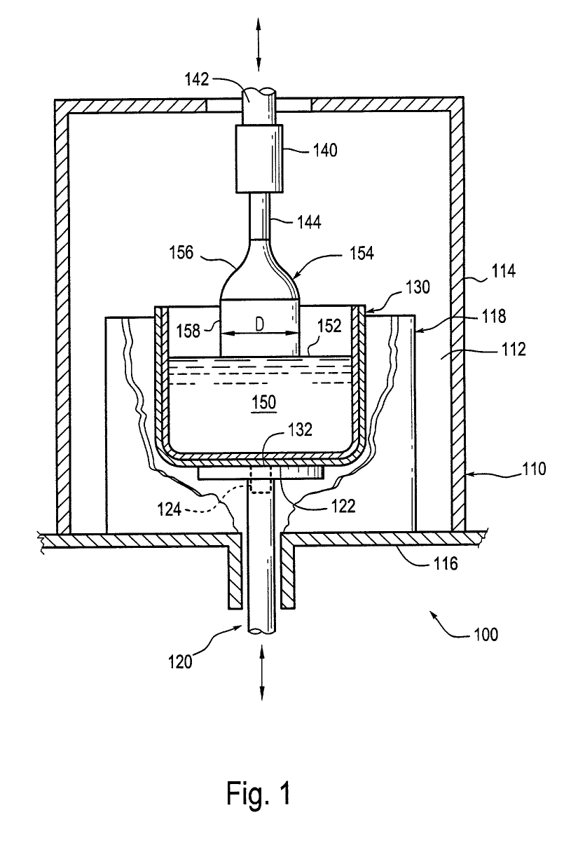

FIG. 1 illustrates a typical crystal growing apparatus 100 for carrying out the well-known Czochralski process. The crystal growing apparatus 100 comprises a specially designed furnace 110 having a heat chamber 112 formed by an insulating structure 114 supported on a platform 116. A heater 118 is provided within the heat chamber 112.

A shaft 120 extends vertically through an opening in the platform 116. The shaft 120 may be provided with a support surface 122 which may include a central recess 24. If the shaft 120 is not provided with the support surface 122, then the central recess 24 may be formed directly in the uppermost end of the shaft 120. The shaft 120 is designed to be rotatable around its axis as well as vertically movable along its axis for reasons described in the above-mentioned references.

Further, the shaft 120, with or without the support surface 122, is adapted to receive a quartz-lined crucible 130. The crucible 130 has a base protrusion 132 which extends downwardly and cooperates with the central recess 24 to mount the crucible 130 on the shaft 120 in proper alignment. Thus, the crucible 130 may be easily removed and replaced.

A graphite chuck 140 is suspended above the crucible 130 by a holder 142. The holder 142 may comprise a cable, wire or shaft that is movable so as to raise and lower the graphite chuck 140. The holder 142 extends vertically through an upper opening in the insulating structure 114 and is generally aligned with the shaft 120 so that the graphite chuck 140 is generally centered over the crucible 130. The graphite chuck 140 is adapted to hold a seed crystal 144.

A quantity of semiconductor material 150, typically silicon, is placed in the crucible 130 and heated by the heater 118 into a molten state. In the molten state, the quantity of semiconductor material 150 defines a melt surface 152 which is the melt level. The graphite chuck 140 is lowered by the holder 142 until the seed crystal 144 contacts the melt surface 152 and is “dipped” into the molten semiconductor material 150.

By slowly withdrawing the seed crystal 144 from the molten semiconductor material 150, a crystal rod 154 is grown. Initially, the graphite chuck 140 is raised at a rate so that the crystal rod 154 is narrow enough to remove dislocations. The rate is then slowed so that a shoulder region 156 is formed until a desired diameter of the crystal rod 154 is reached and maintained to form a body portion 158.

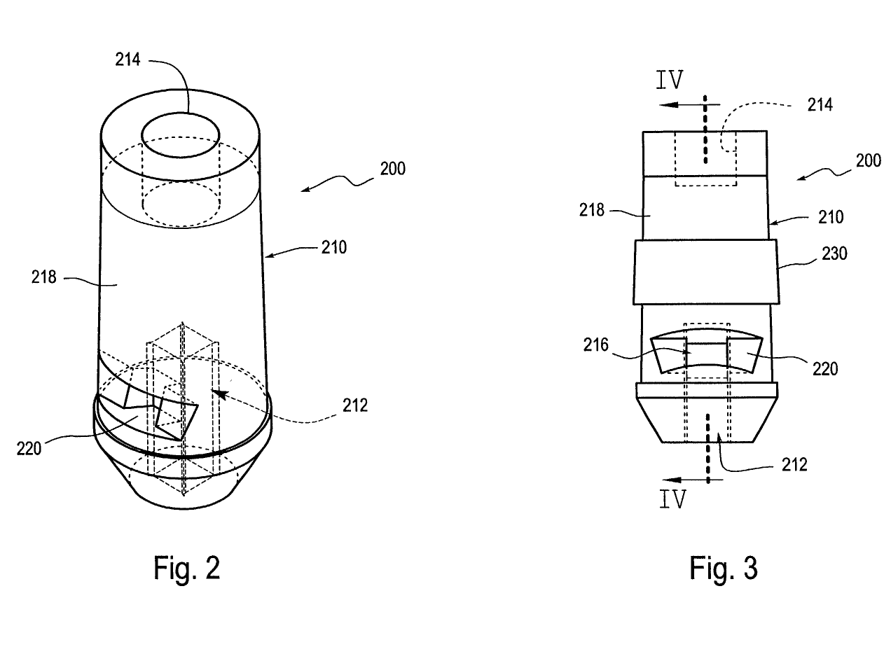

An exemplary embodiment of a chucking system 200 according to this invention is shown in FIGS. 2-7. This invention provides an improved design for the graphite chuck 140 shown in FIG. 1.

The chucking system 200 comprises a chuck body 210 and a chuck stopper 220. As shown in FIG. 2, the chuck stopper 220 is formed to mate with the chuck body 210 in a manner described in more detail below. The chuck body 210 defines an axial bore 212 for receiving an object to be chucked, such as the seed crystal 144 described with respect to FIG. 1. The chuck body 210 may also include a second axial bore 214, such as a threaded bore, as shown, or any other suitable arrangement at an end opposite the axial bore 212 for connecting to, for example, the holder 142 described with respect to FIG. 1.

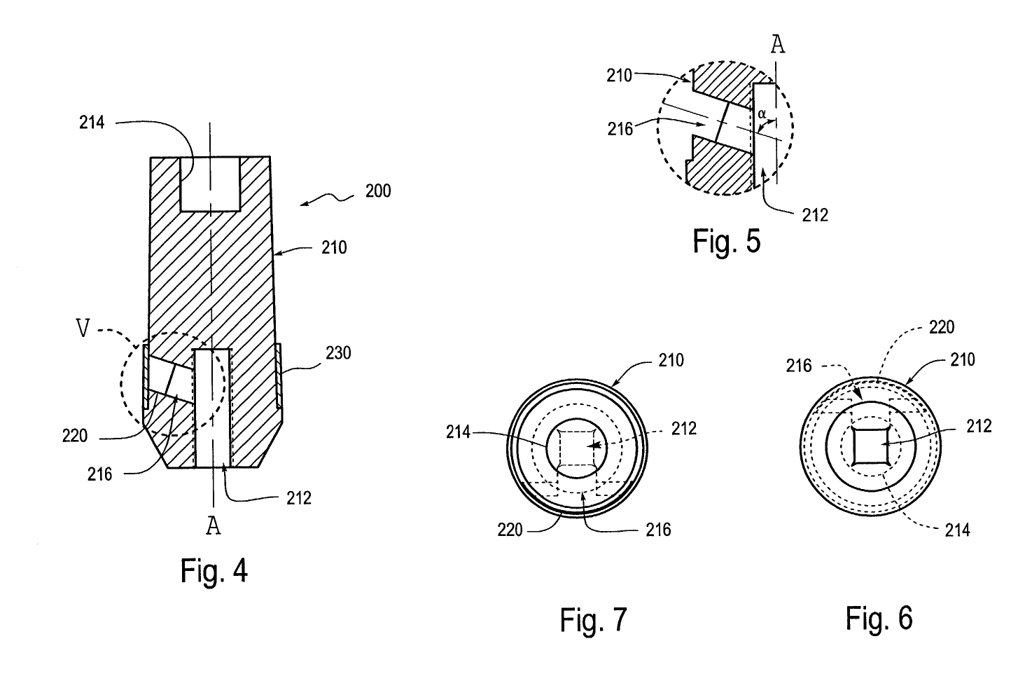

The chuck body 210 also defines a radially inclined bore 216 for receiving the chuck stopper 220. Radially inclined means that an axis of the radially inclined bore 216 forms a non-zero angle other than ninety degrees with respect to an axis A of the axial bore 212. As shown in the enlarged partial view of FIG. 4, the axis of the radially inclined bore 216 forms an angle α with respect to the axis A of the axial bore 212. The angle α is between zero and ninety degrees. Preferably, the angle α is between about forty-five and ninety degrees. The radially inclined bore may be inclined at an angle of about eighty-eight degrees, about eighty-five degrees, about eighty degrees, about seventy-five degrees, about seventy degrees, about sixty-five degrees, about sixty degrees, about fifty-five degrees, or about forty degrees. In the exemplary embodiment of FIGS. 2-7, the angle α. is about seventy degrees. As best seen in FIGS. 2-5, the radially inclined bore 216 opens at least partially into the axial bore 212.

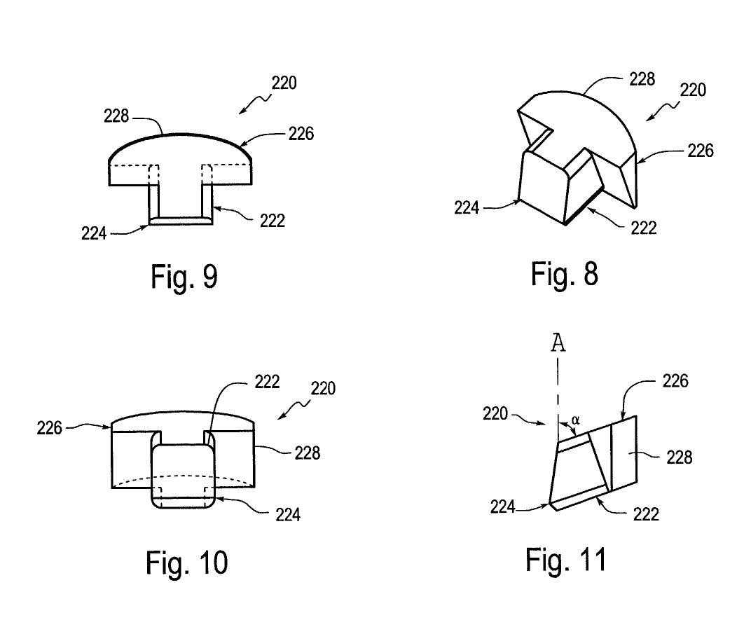

An insertion end 222 of the chuck stopper 220, shown in detail in FIGS. 8-11, extends at least partially into the axial bore 212 when the chuck stopper 220 is fitted into the radially inclined bore 216 in a desired chucking position. For example, the desired chucking position of the chuck stopper 220 may be one in which only a bit 224 of the chuck stopper 220 extends into the axial bore 212 to engage a complementary shape formed in the seed crystal. As much or as little of the chuck stopper 220 may extend into the axial bore 212 as needed to ensure chucking engagement of the seed crystal.

As shown in FIGS. 2-4 and 6-7, according to the exemplary embodiment, the chuck body 210 has a tapered cylindrical outer surface 218. The outer surface 218, however, need not be tapered or cylindrical, but may be any suitable shape. For example, the chuck body 210 may have an outer surface that runs parallel to the axis of the axial bore 212. Further, the chuck body 210 may have an outer surface with an elliptical, oval, or even polygonal perimeter.

Preferably, the chuck stopper 220 mates with the chuck body 210 so that a curved surface 228 of an outer end 226 of the chuck stopper 220 is flush with the outer surface 218 when the chuck stopper 220 is in the desired chucking position. Once flush, the chuck stopper 220 may be temporarily fixed in the desired chucking position by fitting a sleeve or ring 230 over the chuck body 210 so as to enclose a perimeter of the chuck body 210 and at least part of the curved surface 228 of the chuck stopper 220. The sleeve 230 is shown fitted over the chuck body 210 in a non-chucking position and in a chucking position in FIGS. 3 and 4, respectively.

Other methods and/or means for maintaining the chuck stopper 220 in the radially inclined bore 216 in the desired chucking position may be used. For example, a pin or screw may be used to releasably connect the chuck stopper 220 to the chuck body 210 at a certain position. Such a pin or screw could be movably mounted in either the chuck stopper 220 or the chuck body 210 as desired. A corresponding hole or threaded bore would be provided in the other of the chuck body 210 or the chuck stopper 220. In either case, the flush fit of the curved surface 228 of the chuck stopper 220 with the outer surface 218 of the chuck body 210 may be used to indicate that the chuck stopper 220 is in the desired chucking position for setting the pin or screw. Also, for example, any suitable clamping arrangement may be used.

Further details of the chuck stopper 220 according to the exemplary embodiment are shown in FIGS. 8-11. The insertion end 222 of the chuck stopper 220 is preferably shaped to fit with the complementary shape formed in the seed crystal or other object to be chucked. For example, the insertion end 222 may have angled faces that form the bit 224. Beveled edges may be provided to facilitate insertion of the insertion end 222 of the chuck stopper 220 into the radially inclined bore 216.

FIG. 11 illustrates the orientation of the chuck stopper 220 when inserted into the radially inclined bore 216. The chuck stopper 220 is disposed at the angle α with respect to the axis A of the axial bore 212. In this exemplary embodiment, the angle α. is about seventy degrees.

Since the weight of the crystal rod 154 that is grown will depend on the desired diameter and the length of the body portion 158, the ability of the chucking system 200 to support greater weights provides greater flexibility to grow crystal rods of greater diameter and/or length.

Since the chuck stopper 220 can only be fully inserted into the radially inclined bore 216 when properly oriented for chucking, chucking errors are reduced. According to the exemplary embodiment, the curved surface 228 of the chuck stopper 220 will be flush with the outer surface 218 of the chuck body 210 only when the chuck stopper 220 is in the desired chucking position, that is, with the bit 224 engaging the complementary shape formed in the seed crystal.

While this invention has been described in conjunction with the exemplary embodiment outlined above, it is evident that many alternatives, modifications and variations will be apparent to those skilled in the art. Accordingly, the exemplary embodiments of the invention, as set forth above, are intended to be illustrative, not limiting. Various changes may be made without departing from the spirit and scope of the invention.

What is claimed is:

1. A chucking system, comprising:
a chuck body defining an axial bore for receiving an object to be chucked, the chuck body including a radially inclined bore that opens at least partially into the axial bore; and
a chuck stopper adapted to fit into the radially inclined bore and extend partially into the axial bore.

2. The system of claim 1, further comprising means for maintaining the chuck stopper in the radially inclined bore in a desired chucking position.

3. The system of claim 2, wherein the means comprises a sleeve adapted to enclose a perimeter of the chuck body and at least a portion of the chuck stopper.

4. The system of claim 3, wherein the portion is a part of an outer surface of the chuck stopper.

5. The system of claim 1, wherein the radially inclined bore is inclined outwardly in a direction away from an open end of the axial bore.

6. The system of claim 1, wherein the radially inclined bore is inclined at an angle of between zero and ninety degrees relative to an axis of the axial bore.

7. The system of claim 6, wherein the angle is between about forty-five and about eighty-eight degrees.

8. The system of claim 7, wherein the angle is about seventy degrees.

9. A chucking method, comprising:
inserting an object to be chucked into an axial bore of a chuck body;
inserting a chuck stopper into a radially inclined bore of the chuck body;
contacting a distal end of the chuck stopper with the object in the axial bore; and
releasably fixing the chuck stopper in the radially inclined bore to chuck the object in the axial bore.

10. The method of claim 9, wherein releasably fixing the chuck stopper in the radially inclined bore comprises enclosing a perimeter of the chuck body and at least a portion of the chock stopper with a sleeve.

11. The method of claim 9, wherein the radially inclined bore is inclined outwardly in a direction away from an open end of the axial bore such that inserting the chuck stopper into the radially inclined bore is inwardly in a direction toward the open end of the axial bore.

12. The method of claim 9, wherein the radially inclined bore is inclined at an angle of between zero and ninety degrees relative to an axis of the axial bore such that inserting the chuck stopper into the radially inclined bore is at the angle of between zero and ninety degrees relative to the axis of the axial bore.

13. The method of claim 9, wherein the radially inclined bore is inclined at an angle of between about forty-five and about eighty-eight degrees such that inserting the chuck stopper into the radially inclined bore is at the angle of between about forty-five and about eighty-eight degrees relative to the axis of the axial bore.

14. The system of claim 9, the radially inclined bore is inclined at an angle of about seventy degrees such that inserting the chuck stopper into the radially inclined bore is at the an angle of about seventy degrees.

15. A method for chucking a seed crystal in a crystal growing apparatus, the method comprising:
inserting a seed crystal into an axial bore of a chuck body;
inserting a chuck stopper into a radially inclined bore of the chuck body;
contacting a distal end of the chuck stopper with the seed crystal in the axial bore; and
releasably fixing the chuck stopper in the radially inclined bore to chuck the seed crystal in the axial bore.

16. The method of claim 15, wherein releasably fixing the chuck stopper in the radially inclined bore comprises enclosing a perimeter of the chuck body and at least a portion of the chock stopper with a sleeve.

17. The method of claim 15, further comprising:
providing the seed crystal with a shaped portion prior to inserting the seed crystal into the axial bore of the chuck body; and
providing the distal end of the chuck stopper with a complementary shape to the shaped portion of the seed crystal;
wherein contacting the distal end of the chuck stopper with the seed crystal in the axial bore comprises mating the distal end with the shaped portion of the seed crystal.

18. The method of claim 15, wherein the radially inclined bore is inclined outwardly in a direction away from an open end of the axial bore such that inserting the chuck stopper into the radially inclined bore is inwardly in a direction toward the open end of the axial bore.

19. The method of claim 15, wherein the radially inclined bore is inclined at an angle of between zero and ninety degrees relative to an axis of the axial bore such that inserting the chuck stopper into the radially inclined bore is at the angle of between zero and ninety degrees relative to the axis of the axial bore.

20. The method of claim 15, wherein the radially inclined bore is inclined at an angle of between about forty-five and about eighty-eight degrees such that inserting the chuck stopper into the radially inclined bore is at the angle of between about forty-five and about eighty-eight degrees relative to the axis of the axial bore.

21. The system of claim 15, the radially inclined bore is inclined at an angle of about seventy degrees such that inserting the chuck stopper into the radially inclined bore is at the an angle of about seventy degrees.
